(19) United States
(12) Patent Application Publication
(10) Pub. No.: US 2024/0412955 A1
(43) Pub. Date: Dec. 12, 2024

(54) TEMPERATURE ADJUSTING SYSTEM, TEMPERATURE ADJUSTING METHOD, SUBSTRATE PROCESSING METHOD, AND SUBSTRATE PROCESSING APPARATUS

(71) Applicants: Tokyo Electron Limited, Tokyo (JP); TAIYO NIPPON SANSO CORPORATION, Tokyo (JP)

(72) Inventors: Masahiko YOKOI, Miyagi (JP); Koki TANAKA, Miyagi (JP); Maju TOMURA, Miyagi (JP); Yoshihide KIHARA, Miyagi (JP); Masahiro YONEKURA, Tokyo (JP)

(73) Assignees: Tokyo Electron Limited, Tokyo (JP); TAIYO NIPPON SANSO CORPORATION, Tokyo (JP)

(21) Appl. No.: 18/810,862

(22) Filed: Aug. 21, 2024

Related U.S. Application Data
(63) Continuation of application No. PCT/JP2022/007982, filed on Feb. 25, 2022.

(51) Int. Cl. H01J 37/32

(52) U.S. Cl. CPC H01J 37/32522; H01J 37/32449; H01J 2237/002; H01J 2237/334

(57) ABSTRACT

A temperature adjusting system is a temperature adjusting system that cools a part in a plasma processing chamber and includes: a condenser that condenses a temperature adjusting medium that is in a gaseous state at normal temperature and normal pressure; a heat exchanger that cools the temperature adjusting medium that has been condensed by the condenser; a temperature adjusting unit that cools the part by heat exchange with the temperature adjusting medium that has been cooled by the heat exchanger; and a pump that circulates the temperature adjusting medium.

### CROSS-REFERENCE TO RELATED APPLICATION

This application is a continuation of International Application No. PCT/JP2022/007982, filed on Feb. 25, 2022, the entire contents of which are incorporated herein by reference.

### FIELD

Exemplary embodiments disclosed herein relate to a temperature adjusting system, a temperature adjusting method, a substrate processing method, and a substrate processing apparatus.

### BACKGROUND

Temperature control in a substrate processing apparatus is implemented by a chiller that circulates a temperature adjusting medium through a flow channel in a placing pedestal by means of a pump. For example, it has been proposed, for an etching process, to circulate a temperature adjusting medium through a flow channel in a placing pedestal, the temperature adjusting medium having been cooled by a chiller, and to thereby control temperature of a wafer via heat transfer gas flowing between the placing pedestal and the wafer (Japanese Laid-open Patent Publication No. 2003-347283).

According to an aspect of embodiments, a temperature adjusting system, a temperature adjusting method, a substrate processing method, and a substrate processing apparatus that are able to be used in a low temperature range are to be provided.

### SUMMARY

An aspect of a present disclosure provides a temperature adjusting system that cools a part in a plasma processing chamber, the temperature adjusting system including: a condenser that condenses a temperature adjusting medium including at least one of C3F8 and C3H2F4; a heat exchanger that cools the temperature adjusting medium that has been condensed by the condenser; a temperature adjusting unit that cools the part to −150° C. or more and −50° C. or less by heat exchange with the temperature adjusting medium that has been cooled by the heat exchanger; and a pump that circulates the temperature adjusting medium.

### BRIEF DESCRIPTION OF DRAWINGS

FIG. 1 is a diagram illustrating an example of a plasma processing system according to a first embodiment of the present disclosure;

FIG. 2 is a diagram illustrating an example of a temperature adjusting system according to the first embodiment;

FIG. 3 is a graph illustrating an example of characteristics of viscosity of temperature adjusting media;

FIG. 4 is a graph illustrating an example of characteristics of vapor pressure of the temperature adjusting media;

FIG. 5 is a flowchart illustrating an example of a temperature adjusting process according to the first embodiment;

FIG. 6 is a flowchart illustrating an example of substrate processing according to a second embodiment;

FIG. 7 is an enlarged sectional view of part of an example of a substrate provided according to the second embodiment;

FIG. 8 is an enlarged sectional view of part of an example of the substrate after execution of a substrate processing method illustrated in FIG. 6;

FIG. 9 is an example of a timing chart related to the substrate processing method according to the second embodiment;

FIG. 10 is a flowchart illustrating an example of substrate processing according to a third embodiment;

FIG. 11 is an enlarged sectional view of part of an example of a substrate provided according to the third embodiment;

FIG. 12A is an enlarged sectional view of part of a substrate in an example, to which a substrate processing method illustrated in FIG. 10 has been applied;

FIG. 12B is an enlarged sectional view of part of a substrate in an example, the substrate having been subjected to etching by plasma formed from a processing gas not including phosphorus; and

FIG. 13 is an example of a timing chart related to the substrate processing method according to the third embodiment.

### DESCRIPTION OF EMBODIMENTS

Exemplary embodiments of a temperature adjusting system, a temperature adjusting method, a substrate processing method, and a substrate processing apparatus disclosed in the present application will be explained below in detail with reference to the accompanying drawings. The present invention is not limited to the embodiments explained below.

High speed etching of silicon-based materials, such as silicon oxide and silicon nitride, by low temperature physical adsorption of hydrogen fluoride has been performed in recent years. However, reaching such a temperature with the existing chiller performance is difficult, due to heat input from plasma. Furthermore, the viscosity of existing temperature adjusting media increases in low temperature ranges and loads on the pumps to circulate the temperature adjusting media are thus increased in some cases. In addition, when the viscosity of a temperature adjusting medium increases, it becomes difficult to achieve the flow needed for cooling. Preventing increase in the viscosity of temperature adjusting media in the temperature zones that they are used is thus hoped for.

Furthermore, temperature adjusting media sometimes dry out due to the heat input from plasma. In such a case, the temperature adjusting medium in the liquid phase collects in a lower region of the flow channel in the temperature adjusting unit and the gaseous phase goes to an upper region in the flow channel. For example, because heat input from an upper surface is cooled in a case where a substrate support unit is to be cooled, any dryout would reduce the cooling performance. There is thus a demand for the vapor pressure of the temperature adjusting media to be sufficiently low. A temperature adjusting medium is thus hoped for, the temperature adjusting medium having vapor pressure that is sufficiently low in consideration of increase in temperature of the temperature adjusting medium due to heat input from plasma. That is, minimizing increase in the viscosity of the temperature adjusting medium in a temperature zone used and a sufficiently low vapor pressure of the temperature adjusting medium in the temperature zone used are hoped for. In other words, use of a temperature adjusting system in a low temperature range is hoped for.

### First Embodiment

### Configuration of Plasma Processing System

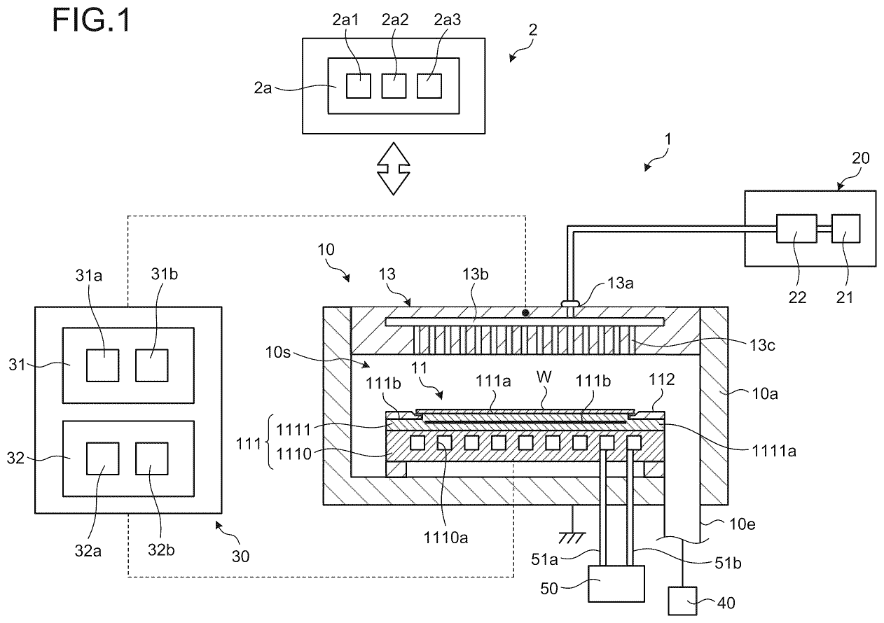

The following description is on an example of a configuration of a plasma processing system. FIG. 1 is a diagram illustrating an example of a plasma processing system according to a first embodiment of the present disclosure. As illustrated in FIG. 1, the plasma processing system includes a plasma processing apparatus 1 of the capacitively coupled type, and a controller 2. The plasma processing apparatus 1 of the capacitively coupled type includes a plasma processing chamber 10, a gas supply unit 20, a power source 30, and an exhaust system 40. The plasma processing apparatus 1 also includes a substrate support unit 11 and a gas introduction unit. The gas introduction unit is configured to introduce at least one processing gas into the plasma processing chamber 10. The gas introduction unit includes a shower head 13. The substrate support unit 11 is arranged in the plasma processing chamber 10. The shower head 13 is arranged above the substrate support unit 11. In one embodiment, the shower head 13 is at least part of a ceiling of the plasma processing chamber 10. The plasma processing chamber 10 has a plasma processing space 10s defined by the shower head 13, a side wall 10a of the plasma processing chamber 10, and the substrate support unit 11. The plasma processing chamber 10 has at least one gas supply port for supplying at least one processing gas to the plasma processing space 10s and at least one gas discharge port for discharging gas from the plasma processing space 10s. The plasma processing chamber 10 is grounded. The shower head 13 and the substrate support unit 11 are electrically insulated from a casing of the plasma processing chamber 10.

The substrate support unit 11 includes a main body 111 and a ring assembly 112. The main body 111 has a central area 111a for supporting a substrate W and a ring-shaped area 111b for supporting the ring assembly 112. Examples of the substrate W include a wafer. The ring-shaped area 111b of the main body 111 surrounds the central area 111a of the main body 111 in a plan view thereof. The substrate W is arranged on the central area 111a of the main body 111, and the ring assembly 112 is arranged on the ring-shaped area 111b of the main body 111 so as to surround the substrate W on the central area 111a of the main body 111. Therefore, the central area 111a is also called a substrate support surface for supporting the substrate W and the ring-shaped area 111b is also called a ring support surface for supporting the ring assembly 112.

In one embodiment, the main body 111 includes a base 1110 and an electrostatic chuck 1111. The base 1110 includes an electroconductive member. The electroconductive member of the base 1110 may function as a lower electrode. The electrostatic chuck 1111 is arranged on the base 1110. The electrostatic chuck 1111 includes a ceramic member 1111a and an electrostatic electrode 1111b that is arranged in the ceramic member 1111a. The ceramic member 1111a has the central area 111a. In one embodiment, the ceramic member 1111a also has the ring-shaped area 111b. Another member, such as a ring-shaped electrostatic chuck or a ring-shaped insulating member, surrounding the electrostatic chuck 1111 may have the ring-shaped area 111b. In this case, the ring assembly 112 may be arranged on the ring-shaped electrostatic chuck or ring-shaped insulating member, or arranged on both the electrostatic chuck 1111 and the ring-shaped insulating member. Furthermore, at least one RF/DC electrode connected to a later described radio frequency (RF) power source 31 and/or a later described direct current (DC) power source 32 may be arranged in the ceramic member 1111a. In this case, the at least one RF/DC electrode functions as a lower electrode. In a case where a later described bias RF signal and/or a later described DC signal are/is supplied to the at least one RF/DC electrode, the RF/DC electrode is also called a bias electrode. The electroconductive member of the base 1110 and the at least one RF/DC electrode may function as plural lower electrodes. Furthermore, the electrostatic electrode 1111b may function as a lower electrode. Therefore, the substrate support unit 11 includes at least one lower electrode.

The ring assembly 112 includes one or more ring-shaped members. In one embodiment, the one or more ring-shaped members include one or more edge rings and at least one cover ring. The edge rings are formed of an electroconductive material or an insulating material and the cover ring is formed of an insulating material.

Furthermore, the substrate support unit 11 may include a temperature adjusting module configured to adjust temperature of at least one of the electrostatic chuck 1111, the ring assembly 112, and the substrate W to a target temperature. The temperature adjusting module may include a heater, a heat transfer medium, a flow channel 1110a, or any combination of the heater, the heat transfer medium, and the flow channel 1110a. A heat transfer fluid, such as brine or gas, flows through the flow channel 1110a. In one embodiment, the flow channel 1110a is formed in the base 1110 and one or more heaters are arranged in the ceramic member 1111a of the electrostatic chuck 1111. For example, a temperature adjusting system 50 described later is connected to the flow channel 1110a via pipes 51a and 51b, and a temperature adjusting medium is supplied to the flow channel 1110a. Furthermore, the substrate support unit 11 may include a heat transfer gas supply unit configured to supply a heat transfer gas into a space between a reverse surface of the substrate W and the central area 111a.

The shower head 13 is configured to introduce at least one processing gas from the gas supply unit 20 into the plasma processing space 10s. The shower head 13 has at least one gas supply port 13a, at least one gas diffusion chamber 13b, and plural gas introduction ports 13c. Processing gas supplied to the gas supply port 13a passes through the gas diffusion chamber 13b and is introduced into the plasma processing space 10s from the plural gas introduction ports 13c. Furthermore, the shower head 13 includes at least one upper electrode. The gas introduction unit may include, in addition to the shower head 13, one or more side gas injectors (SGIs) attached to one or more openings formed in the side wall 10a.

The gas supply unit 20 may include at least one gas source 21 and at least one flow controller 22. In one embodiment, the gas supply unit 20 is configured to supply each of the at least one processing gas from the gas source 21 corresponding to the processing gas via the flow controller 22 corresponding to the processing gas to the shower head 13. Each of the at least one flow controller 22 may include, for example, a mass flow controller or a pressure controlling flow controller. Furthermore, the gas supply unit 20 may include one or more flow modulation devices that modulate or pulse flows of the at least one processing gas.

The power source 30 includes the RF power source 31 connected to the plasma processing chamber 10 via at least one impedance matching circuit. The RF power source 31 is configured to supply at least one RF signal (RF power) to the at least one lower electrode and/or the at least one upper electrode. Plasma is thereby formed from the at least one processing gas supplied to the plasma processing space 10s. Therefore, the RF power source 31 may function as at least part of a plasma generation unit configured to generate plasma from one or more processing gases in the plasma processing chamber 10. Furthermore, supplying a bias RF signal to the at least one lower electrode generates bias potential in the substrate W and enables ion components to be attracted into the substrate W, the ion components being in the plasma generated.

In one embodiment, the RF power source 31 includes a first RF generator 31a and a second RF generator 31b. The first RF generator 31a is configured to be connected to the at least one lower electrode and/or the at least one upper electrode via the at least one impedance matching circuit and to generate a source RF signal (source RF power) for plasma generation. In one embodiment, the source RF signal has a frequency in a range of 10 MHz to 150 MHz. In one embodiment, the first RF generator 31a may be configured to generate plural source RF signals having different frequencies. The one or more source RF signals generated are supplied to the at least one lower electrode and/or the at least one upper electrode.

The second RF generator 31b is configured to be connected to the at least one lower electrode via the at least one impedance matching circuit and to generate a bias RF signal (bias RF power). The bias RF signal may have a frequency that is the same as or different from the frequency of the source RF signal. In one embodiment, the bias RF signal has a frequency lower than the frequency of the source RF signal. In one embodiment, the bias RF signal has a frequency in a range of 100 kHz to 60 MHz. In one embodiment, the second RF generator 31b may be configured to generate plural bias RF signals having different frequencies. The one or more bias RF signals generated are supplied to the at least one lower electrode. In various embodiments, at least one of the source RF signal and the bias RF signal may be pulsed.

Furthermore, the power source 30 may include the DC power source 32 connected to the plasma processing chamber 10. The DC power source 32 includes a first DC generator 32a and a second DC generator 32b. In one embodiment, the first DC generator 32a is configured to be connected to the at least one lower electrode and to generate a first DC signal. The first DC signal generated is applied to the at least one lower electrode. In one embodiment, the second DC generator 32b is configured to be connected to the at least one upper electrode and to generate a second DC signal. The second DC signal generated is applied to the at least one upper electrode.

In various embodiments, at least one of the first and second DC signals may be pulsed. In this case, a sequence of voltage pulses is applied to the at least one lower electrode and/or the at least one upper electrode. The voltage pulses may have a rectangular pulse waveform, a trapezoidal pulse waveform, a triangular pulse waveform, or any combination of these pulse waveforms. In one embodiment, a waveform generator for generating a sequence of voltage pulses from a DC signal is connected between the first DC generator 32a and the at least one lower electrode. Therefore, the first DC generator 32a and the waveform generator compose a voltage pulse generator. In a case where the second DC generator 32b and the waveform generator compose a voltage pulse generator, the voltage pulse generator is connected to the at least one upper electrode. The voltage pulses may have a positive polarity or a negative polarity. Furthermore, the sequence of voltage pulses may include one or more positive polarity voltage pulses and one or more negative polarity voltage pulses in one period. The first and second DC generators 32a and 32b may be provided additionally to the RF power source 31 and the first DC generator 32a may be provided instead of the second RF generator 31b.

The exhaust system 40 may be connected to a gas discharge port 10e provided at a bottom portion of the plasma processing chamber 10, for example. The exhaust system 40 may include a pressure regulating valve and a vacuum pump. Pressure in the plasma processing space 10s is regulated by the pressure regulating valve. The vacuum pump may include a turbo molecular pump, a dry pump, or a combination of these pumps.

The temperature adjusting system 50 supplies a temperature adjusting medium via the pipes 51a and 51b to the flow channel 1110a in the base 1110 to adjust temperature of the substrate W placed on the central area 111a of the main body 111 to the target temperature (predetermined temperature). The target temperature may be a temperature of the electrostatic chuck 1111 or the ring assembly 112, for example. The temperature adjusting system 50 performs control such that the substrate W has the predetermined temperature, for example, −70° C., by controlling, for example, the temperature adjusting medium flowing through the flow channel 1110a and a heater not illustrated in the drawings.

The controller 2 processes computer executable commands that cause the plasma processing apparatus 1 to execute various processes described in the present disclosure. The controller 2 may be configured to control each component of the plasma processing apparatus 1 to execute the various processes described herein. In one embodiment, part or all of the controller 2 may be included in the plasma processing apparatus 1. The controller 2 may include a processing unit 2al, a storage 2a2, and a communication interface 2a3. The controller 2 is implemented by, for example, a computer 2a. The processing unit 2al may be configured to perform various kinds of control operation by reading a program from the storage 2a2 and executing the program read. This program may be stored in the storage 2a2 beforehand, or may be obtained via a medium when needed. The program obtained is stored in the storage 2a2, read by the processing unit 2al from the storage 2a2, and executed by the processing unit 2al. The medium may be any of various storage media readable by the computer 2a or may be a communication line connected to the communication interface 2a3. The processing unit 2al may be a central processing unit (CPU). The storage 2a2 may include a random access memory (RAM), a read only memory (ROM), a hard disk drive (HDD), a solid state drive (SSD), or any combination of these memories and drives. The communication interface 2a3 may implement communication to and from the plasma processing apparatus 1 via a communication line, such as a local area network (LAN).

### Details of Temperature Adjusting System 50

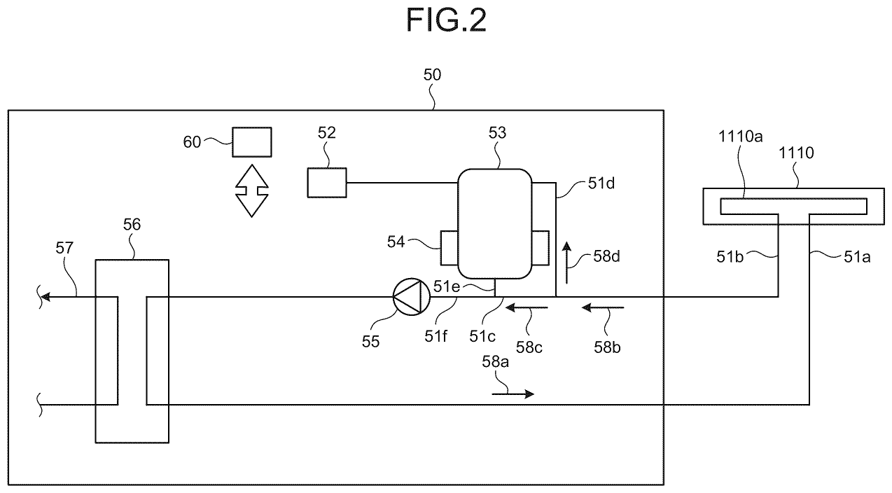

Details of the temperature adjusting system 50 will be described next by use of FIG. 2. FIG. 2 is a diagram illustrating an example of a temperature control system according to the first embodiment. As illustrated in FIG. 2, the temperature adjusting system 50 has a gas supply unit 52, a condenser 53, a cooling jacket 54, a pump 55, and a heat exchanger 56. Furthermore, the temperature adjusting system 50 has a controller 60 that controls each of the gas supply unit 52, the condenser 53, the cooling jacket 54, the pump 55, and the heat exchanger 56, according to instructions from the controller 2.

The gas supply unit 52 supplies a temperature adjusting medium that is in a gaseous state at normal temperature and normal pressure, to the condenser 53. For example, the gas supply unit 52 supplies a gas, such as C3F8 or C3H2F4, as the temperature adjusting medium, to the condenser 53.

The condenser 53 condenses the temperature adjusting medium, which is in the gaseous state and has been supplied from the gas supply unit 52, into liquid. The condenser 53 is, for example an airtight tank, and the temperature adjusting medium inside the condenser 53 is liquefied by the condenser 53 being cooled by the cooling jacket 54. Increasing pressure inside the condenser 53 to a pressure higher than atmospheric pressure liquefies the temperature adjusting medium at a temperature higher than its boiling point at atmospheric pressure. If performance of the cooling jacket 54 allows the temperature adjusting medium to be cooled to the boiling point or lower at atmospheric pressure, the pressure inside the condenser 53 may be at atmospheric pressure.

The pump 55 circulate the temperature adjusting medium, which is in the liquid phase and has been liquefied by the condenser 53, through the heat exchanger 56 and the flow channel 1110a in the base 1110. The pump 55 is capable of making the flow of the temperature adjusting medium, in circulating the temperature adjusting medium, to, for example, 15 L/min or more.

The heat exchanger 56 cools the temperature adjusting medium liquefied by the condenser 53 into the liquid phase. The heat exchanger 56 cools the temperature adjusting medium to a predetermined temperature by means of a coolant, such as liquid nitrogen or liquid helium, for example. The predetermined temperature may be, for example, a temperature in a range of −50° C. to −150° C. The coolant is supplied through a pipe 57 to the heat exchanger 56 from a coolant supply source not illustrated in the drawings. The heat exchanger 56 cools the temperature adjusting medium flowing in from a pipe 51f near the pump 55 to the predetermined temperature by means of the coolant and supplies the temperature adjusting medium cooled, to the pipe 51a.

The pipe 51a is a pipe where the temperature adjusting medium flows out from the temperature adjusting system 50 and is connected to an outlet of the heat exchanger 56. The pipe 51b is a pipe where the temperature adjusting medium flows into the temperature adjusting system 50 and the pipe 51b branches into a pipe 51c and a pipe 51d in the temperature adjusting system 50. The pipe 51c is a pipe that allows liquid part of the temperature adjusting medium flowing in the pipe 51b to circulate through the pump 55. The pipe 51d is a pipe that is connected to an upper portion of the condenser 53 and that returns vaporized gas (part that has turned into the gaseous phase) of the temperature adjusting medium flowing in the pipe 51b to the upper portion of the condenser 53. A pipe 51e connected to a lower portion of the condenser 53 joins the pipe 51c to serve as a pipe 51f. That is, the temperature adjusting medium in the liquid phase flows through the pipe 51f. The pipe 51f is connected to the heat exchanger 56 via the pump 55. That is, the temperature adjusting medium in the liquid phase circulates through a flow channel including the pipe 51a, the flow channel 1110a, the pipe 51b, the pipe 51c, the pipe 51f, the pump 55, and the heat exchanger 56. The circulating temperature adjusting medium in the liquid phase has a pressure that is equal to or higher than atmospheric pressure.

The temperature adjusting medium is firstly condensed into liquid by the condenser 53 and supplied to the pipe 51f via the pipe 51e. The temperature adjusting medium in the liquid phase in the pipe 51f is sent to the heat exchanger 56 by the pump 55. The temperature adjusting medium in the liquid phase is supplied to the flow channel 1110a through the pipe 51a from the heat exchanger 56, as indicated by an arrow 58a. The base 1110 is cooled through heat exchange with the temperature adjusting medium in the flow channel 1110a. The electrostatic chuck 1111 is cooled by the base 1110 being cooled, and the substrate W placed on the central area 111a of the electrostatic chuck 1111 is thereby cooled. The temperature adjusting medium may include the gaseous phase due to the heat exchange in the flow channel 1110a. That is, the temperature adjusting medium after the heat exchange is allowed to include the gaseous phase in the flow channel 1110a in the base 1110. The base 1110 is an example of a temperature adjusting unit that cools a part (the electrostatic chuck 1111 and/or the substrate W) through heat exchange with the temperature adjusting medium that has been cooled by the heat exchanger 56.

The following description is on temperature of the substrate W, which is a target of temperature control. Heat is input to the substrate W from plasma and heat is released to the temperature adjusting medium via the electrostatic chuck 1111 and the base 1110. Because the release of heat is proportional to the flow of the temperature adjusting medium and the temperature difference, the temperature of the substrate W is inversely proportional to the flow of the temperature adjusting medium. For example, in a case where the RF power to generate the plasma is 2 kW, if the flow of the temperature adjusting medium is 3 m³/h, the temperature of the substrate W can be found to be −92° C. In view of the above described conditions, even if the RF power to generate the plasma is 1 kW or more, increasing the flow of the temperature adjusting medium (C3F8 or C3H2F4) according to the embodiment enables the temperature of the substrate W to be at the predetermined temperature (for example, −50° C.) or lower. Because the vapor pressure of the temperature adjusting medium (C3F8 or C3H2F4) according to the embodiment is sufficiently low as described later, degradation of the cooling performance due to any dryout is able to be minimized.

The temperature adjusting medium after the heat exchange flows out from the flow channel 1110a to the pipe 51b, as indicated by an arrow 58b. The liquid phase part of the temperature adjusting medium flowing through the pipe 51b flows into the pump 55 via the pipes 51c and 51f, as indicated by an arrow 58c. Furthermore, the temperature adjusting medium in the liquid phase corresponding to an amount of decrease due to evaporation is supplied from the condenser 53 via the pipe 51e. The gaseous phase part of the temperature adjusting medium flowing through the pipe 51b is returned to the upper portion of the condenser 53 via the pipe 51d, as indicated by an arrow 58d. By repeating such a cycle, the temperature adjusting medium circulates between the temperature adjusting system 50 and the base 1110.

### Physical Properties of Temperature Adjusting Medium

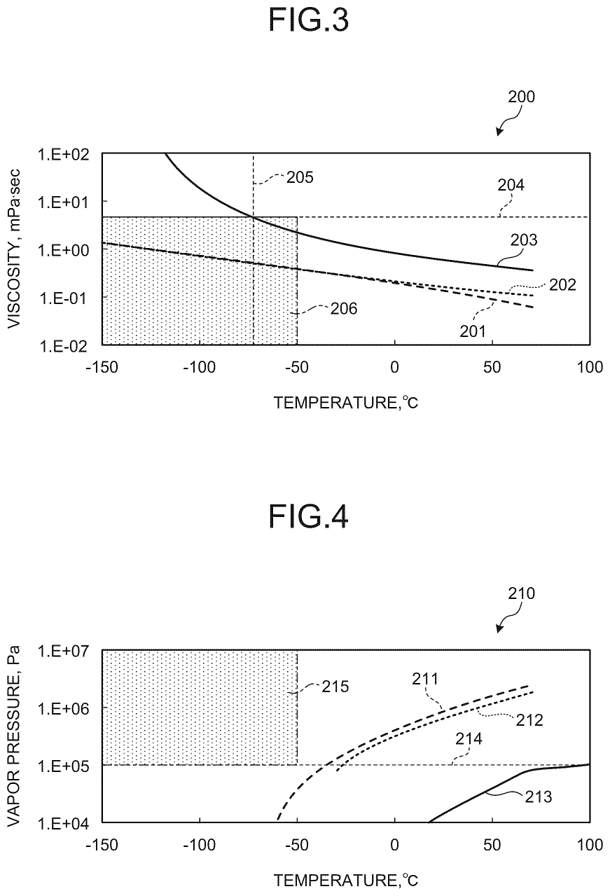

Physical properties of temperature adjusting media will be described next by use of FIG. 3 and FIG. 4. FIG. 3 is a graph illustrating an example of characteristics of viscosity of the temperature adjusting media. A graph 200 illustrated in FIG. 3 is a graph having viscosity (mPa·sec) of each temperature adjusting medium on the vertical axis and temperature (C) on the horizontal axis. A graph 201 is a graph representing the viscosity of C3F8. A graph 202 is a graph representing the viscosity of C3H2F4 (R1234yf). A graph 203 is a graph representing the viscosity of conventional and ordinary brine. A line 204 is a line indicating an upper limit value (6 mPa·sec) of the viscosity for use as the coolant. A line 205 is a line indicating −70° C. as an example of a temperature for use as the coolant. An area 206 is an area defined by a predetermined temperature range for use as the coolant and the upper limit of the viscosity.

In this embodiment, the predetermined temperature range for use as the coolant is from −50° C. to −150° C. and the graphs thus need to be in the area 206 in this temperature range. The graphs 201 and 202 are positioned in the area 206 in this predetermined temperature range and thus indicate that C3F8 and C3H2F4 are suitable as the temperature adjusting medium. By contrast, the graph 203 in this predetermined temperature range is outside the area 206 at temperatures equal to or lower than −70° C. although part of the graph 203 passes through the area 206, and thus indicates that the viscosity does not fulfill the condition and the conventional and ordinary brine is not suitable as the temperature adjusting medium according to this embodiment.

FIG. 4 is a graph illustrating an example of characteristics of vapor pressure of the temperature adjusting media. A graph 210 illustrated in FIG. 4 is a graph having vapor pressure (Pa) of each temperature adjusting medium on the vertical axis and temperature (° C.) on the horizontal axis. A graph 211 is a graph representing the vapor pressure of C3F8. A graph 212 is a graph representing the vapor pressure of C3H2F4 (R1234yf). A graph 213 is a graph representing the vapor pressure of the conventional and ordinary brine. A line 214 is a line indicating a lower limit value (standard atmospheric pressure: 1013.25 hPa) of vapor pressure for use as the coolant. An area 215 is an area defined by the predetermined temperature range for use as the coolant and the lower limit of the vapor pressure.

In this embodiment, the predetermined temperature range for use as the coolant is from −50° C. to −150° C. and the area 215 thus needs to be included in the range of the liquid phase in this temperature range. For the graphs 211 and 212, the area 215 is included in the range of the liquid phase in the predetermined temperature range and thus indicate that C3F8 and C3H2F4 are suitable as the temperature adjusting medium. That is, C3F8 and C3H2F4 are in the liquid phase in an equilibrium state at the predetermined temperature and at atmospheric pressure or more. In a nonequilibrium state where the temperature adjusting medium flows as fluid while circulating, the temperature adjusting medium may include the gaseous phase. For the graph 213, the area 215 is included in the range of the liquid phase in the predetermined temperature range and the conventional and ordinary brine thus also satisfies the condition of the temperature adjusting medium for vapor pressure. That is, as indicated by the graphs 200 and 210 in FIG. 3 and FIG. 4, C3F8 and C3H2F4 are suitable as the temperature adjusting medium in terms of conditions for both viscosity and vapor pressure. That is, using a temperature adjusting medium that has a graph positioned in the area 206 of the graph 200 and that is in the liquid phase over a range including the area 215 of the graph 210 enables minimization of increase in viscosity of the temperature adjusting medium in the temperature zone used. Furthermore, C3F8 and C3H2F4 are temperature adjusting media having vapor pressure that is sufficiently low in consideration of increases in temperature of the temperature adjusting media due to heat input from plasma. Without being limited to C3F8 and C3H2F4 mentioned above, any other substance having viscosity in the area 206 of the graph 200 and being in the liquid phase over a range including the area 215 of the graph 210 in terms of vapor pressure may be used as the temperature adjusting medium.

### Temperature Adjusting Method

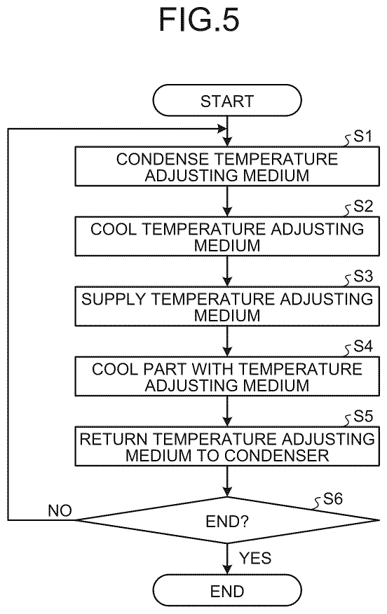

A temperature adjusting process according to the first embodiment will be described next. FIG. 5 is a flowchart illustrating an example of the temperature adjusting process according to the first embodiment.

In the temperature adjusting process according to the first embodiment, firstly, in response to a start of the temperature process being instructed by the controller 2, the controller 60 of the temperature adjusting system 50 causes the gas supply unit 52 to start supplying a temperature adjusting medium that is in a gaseous state at normal temperature and normal pressure, to the condenser 53. The controller 60 causes the temperature adjusting medium in the gaseous state to be condensed into liquid in the condenser 53 (Step S1).

The controller 60 causes the pump 55 to operate to cause the temperature adjusting medium to circulate through the heat exchanger 56 and causes the temperature adjusting medium to be cooled in the heat exchanger 56 (Step S2). The controller 60 causes the temperature adjusting medium to be supplied to the base 1110 that is the temperature adjusting unit to cool a part (the electrostatic chuck 1111 and/or the substrate W), the temperature adjusting medium having been cooled by the heat exchanger 56 (Step S3). The controller 60 performs control to cause the part to be cooled by the temperature adjusting medium at the base 1110 by causing circulation of the temperature adjusting medium (Step S4) and to return the temperature adjusting medium after heat exchange to the condenser 53 (Step S5).

The controller 60 determines whether or not the controller 2 has instructed to end the temperature adjusting process, that is, whether or not the temperature adjusting process is to be ended (Step S6). In a case where the controller 60 has determined that the temperature adjusting process is not to be ended (Step S6: No), the controller 60 returns to Step S1. On the contrary, in a case where the controller 60 has determined that the temperature adjusting process is to be ended (Step S6: Yes), the controller 60 ends the temperature adjusting process.

### Second Embodiment

A substrate processing method using the temperature adjusting method according to the first embodiment will be described next as a second embodiment. A substrate processing apparatus in the second embodiment has a configuration similar to that of the first embodiment and description of any component and any operation that are the same will thus be omitted.

### Substrate Processing Method

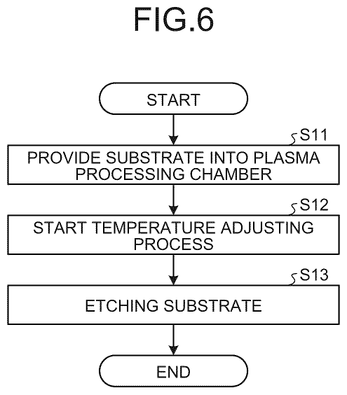

A substrate processing method using the above mentioned temperature adjusting method will be described by use of FIG. 6 to FIG. 9. FIG. 6 is a flowchart illustrating an example of substrate processing according to the second embodiment. The substrate processing method illustrated in FIG. 6 is executed for subjecting a film containing silicon to etching. This substrate processing method may be used in manufacture of a NAND flash memory having a three-dimensional structure, for example. The substrate processing method is executed by use of a plasma processing system.

The controller 2 controls the plasma processing apparatus 1 so that a substrate W1 is provided into the plasma processing chamber 10 (Step S11). The substrate W1 is placed on the electrostatic chuck 1111 and held by the electrostatic chuck 1111.

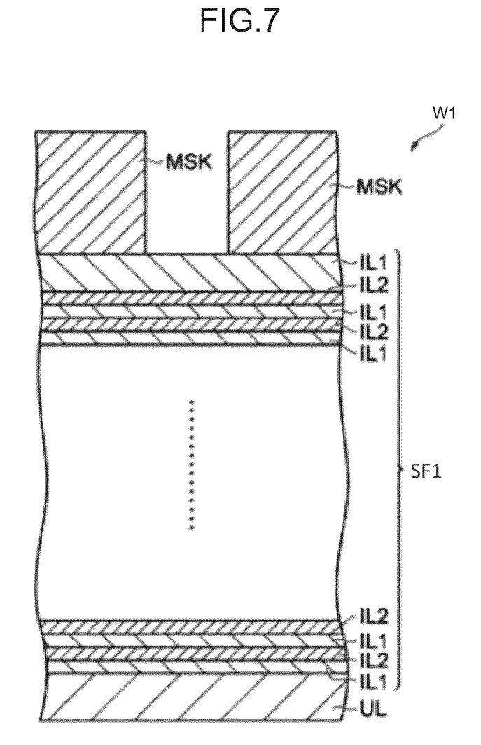

FIG. 7 is an enlarged sectional view of part of an example of a substrate provided according to the second embodiment. The substrate W1 illustrated in FIG. 7 has an underlayer UL, a film SF1, and a mask MSK. The underlayer UL may be a layer made of polycrystalline silicon. The film SF1 is provided on the underlayer UL. The film SF1 contains silicon. The film SF1 may be a stacked film including one or more silicon oxide films and one or more silicon nitride films. In the example illustrated in FIG. 7, the film SF1 is a multilayered film including plural silicon oxide films IL1 and plural silicon nitride films IL2. The plural silicon oxide films IL1 and the plural silicon nitride films IL2 are alternately layered over each other. The film SF1 may be a single-layered film including silicon or another multilayered film including silicon. In a case where the film SF1 is a single-layered film, for example, the film SF1 may be a low dielectric constant film formed from SiOC, SiOF, or SiCOH, or may be a polysilicon film. Or in a case where the film SF1 is a multilayered film, the film SF1 may be a stacked film including, for example, one or more silicon oxide films and one or more polysilicon films.

The mask MSK is provided on the film SF1. The mask MSK has a pattern for forming a space, such as a hole, in the film SF1. The mask MSK may be, for example, a hard mask. The mask MSK may be, for example, a carbon-containing mask and/or a metal-containing mask. The carbon-containing mask is formed from at least one kind selected from a group consisting of, for example, spin-on carbon, tungsten carbide, amorphous carbon, and boron carbide. The metal-containing mask is formed of at least one kind selected from a group consisting of titanium nitride, titanium oxide, and tungsten. Or the mask MSK may be a boron-containing mask formed from, for example, silicon boride, boron nitride, or boron carbide.

The controller 2 controls the temperature adjusting system 50 to start the temperature adjusting process such that temperature of the substrate support unit 11 (the electrostatic chuck 1111 and the substrate W1) becomes a predetermined temperature (Step S12). That is, the controller 2 instructs the controller 60 of the temperature adjusting system 50 to execute the temperature adjusting process according to the first embodiment. The temperature adjusting process is the same as that of the first embodiment and description thereof will thus be omitted.

When temperature of the substrate W1 reaches the predetermined temperature through the temperature adjusting process, the controller 2 controls the plasma processing apparatus 1 to execute a process of subjecting the substrate W1 to etching (Step S13). At Step S13, plasma is generated from a first processing gas in the plasma processing chamber 10. At Step S13, the film SF1 is subjected to etching by means of a chemical species from the plasma.

The first processing gas used at Step S13 includes hydrogen fluoride gas. The flow of hydrogen fluoride gas is more than the flow of any other gas included in the first processing gas excluding inert gas. Specifically, the flow of hydrogen fluoride gas at Step S13 may be 70% by volume or more, 80% by volume or more, 85% by volume or more, 90% by volume or more, or 95% by volume or more, in relation to the total flow of the first processing gas excluding inert gas. In terms of reducing shape anomalies including bowing in the film SF1, in a case where a carbon-containing gas is added, for example, the flow of hydrogen fluoride gas may be 100% by volume or less, 99.5% by volume or less, 98% by volume or less, or 96% by volume or less, in relation to the total flow of the first processing gas excluding inert gas. In one example, the flow of hydrogen fluoride gas is adjusted to 70% by volume or more and 96% by volume or less, in relation to the total flow of the first processing gas excluding inert gas. Controlling the flow of hydrogen fluoride gas in the first processing gas excluding inert gas to be in such a range enables etching of the film SF1 at a high etching speed while minimizing etching of the mask MSK. As a result, the selection ratio of the etching of the silicon-containing film to the etching of the mask is able to be made 5 or larger. Therefore, even for a process requiring a high aspect ratio, such as a process for a NAND flash memory having a three-dimensional structure, etching of the film SF1 is able to be performed at a viable speed. Furthermore, because of such a high selection ratio, the amount of deposition gas added is able to be minimized, the deposition gas being, for example, a carbon-containing gas, the risk of blockage occurring in the mask MSK is thus able to be reduced, and the cleaning time in the plasma processing chamber 10 is able to be reduced to 50% or less. As a result, the throughput of the substrate processing is able to be improved largely. However, in a case where the flow of hydrogen fluoride gas is equal to or less than the flow of any other gas included in the first processing gas excluding inert gas, the selection ratio may be unable to be improved sufficiently. The total flow of the first processing gas excluding inert gas may be adjusted as appropriate according to the chamber volume, and in one example, the total flow may be 100 sccm or more.

The first processing gas may include a carbon-containing gas in addition to the hydrogen fluoride gas. Furthermore, the first processing gas may include, in addition to the hydrogen fluoride gas and the carbon-containing gas, at least one kind selected from a group consisting of an oxygen-containing gas and a halogen-containing gas.

In a case where the first processing gas includes a carbon-containing gas, a deposit including carbon is formed on a mask surface and the selection ratio of the etching of the silicon-containing film to the etching of the mask is thus able to be improved further. The carbon-containing gas includes, for example, at least one kind selected from a group consisting of a fluorocarbon gas, a hydrofluorocarbon gas, and a hydrocarbon gas. For example, CF4, C2F2, C2F4, C3F8, C4F6, C4F8, or C5F8 may be used as the fluorocarbon gas. For example, CHF3, CH2F2, CH3F, C2HF5, C2H2F4, C2H3F3, C2H4F2, C3HF7, C3H2F2, C3H2F6, C3H2F4, C3H3F5, C4H5F5, C4H2F6, C5H2F10, c-C5H3F7, or C3H2F4 may be used as the hydrofluorocarbon gas. For example, CH4, C2H6, C3H6, C3H8, or C4H10 may be used as the hydrocarbon gas. The carbon-containing gas may additionally include CO and/or CO2. In one example, a fluorocarbon gas and/or a hydrofluorocarbon gas each having a carbon number of 2 or more may be used as the carbon-containing gas. In a case where a fluorocarbon gas and/or a hydrofluorocarbon gas each having a carbon number of 2 or more is used, shape anomalies including bowing are able to be reduced effectively. Using a fluorocarbon gas and/or a hydrofluorocarbon gas each having a carbon number of 3 or more enables further reduction of shape anomalies. For example, C4F8 may be used as the fluorocarbon gas having a carbon number of 3 or more. The hydrofluorocarbon gas having a carbon number of 3 or more may include an unsaturated bond and may include one or more CF3 groups. For example, C3H2F4 or C4H2F6 may be used as the hydrofluorocarbon gas having a carbon number of 3 or more.

In a case where the first processing gas includes an oxygen-containing gas, blockage in the mask upon etching is able to be minimized. For example, at least one kind selected from a group consisting of O2, CO, CO2, H2O, and H2O2 may be used as the oxygen-containing gas.

In a case where the first processing gas includes a halogen-containing gas, the etching profile is able to be controlled. The halogen-containing gas that may be used is, for example, at least one kind selected from the group consisting of: a fluorine-containing gas not including carbon, such as SF6, NF3, XeF2, SiF4, IF7, ClF5, BrF5, AsF5, NF5, PF3, PF5, POF3, BF3, HPF6, or WF6; a chlorine-containing gas, such as Cl2, SiCl2, SiCl4, CCl4, BCl3, PCl3, PCl5, or POCl3; a bromine-containing gas, such as HBr, CBr2F2, C2F5Br, PBr3, PBr5, or POBr3; and an iodine-containing gas, such as HI, CF3I, C2F5I, C3F7I, IF5, IF7, I2, or PI3.

The first processing gas may additionally include a gas having a side wall protecting effect, for example: a sulfur-containing gas, such as COS; a phosphorus-containing gas, such as P4O10, P4O8, P4O6, PH3, Ca3P2, H3PO4, or Na3PO4; or a boron-containing gas, such as B2H6. Examples of the phosphorus-containing gas having the side wall protecting effect include a phosphorus fluoride gas, such as PF3 or PF5 mentioned above, or a phosphorus halide gas containing a phosphorus chloride gas, such as PCl3 or PCl5.

In the second embodiment according to the present disclosure, the first processing gas includes: hydrogen fluoride; and at least one kind of carbon-containing gas selected from a group consisting of a fluorocarbon gas and a hydrofluorocarbon gas. The carbon-containing gas may be the fluorocarbon gas mentioned above or the hydrofluorocarbon gas mentioned above. The fluorocarbon gas may be C4F8. The hydrofluorocarbon gas may be one kind selected from a group consisting of C3H2F4 and C4H2F6.

In the second embodiment, the first processing gas may further include at least one kind selected from a group consisting of an oxygen-containing gas and a halogen-containing gas. In this case, the halogen-containing gas may be at least one kind selected from a group consisting of: a halogen-containing gas containing a halogen element other than fluorine; and a fluorine-containing gas not including carbon.

In the second embodiment, at least one kind of additive gas selected from a group consisting of a sulfur-containing gas, a phosphorus-containing gas, and a boron-containing gas that have side wall protecting effects may be additionally included.

The first processing gas may include an inert gas, in addition to these types of gases. Examples of the inert gas that may be used include noble gases, such as Ar, Kr, and Xe, in addition to nitrogen gas. However, the ratio of the flow of the hydrogen fluoride gas to the total flow of the first processing gas excluding the inert gas is controlled to be at the above mentioned ratio.

To execute Step S13, the controller 2 controls the gas supply unit 20 to supply the above described processing gas into the plasma processing chamber 10. To execute Step S13, the controller 2 controls the gas supply unit 20 such that the flow of the hydrogen fluoride gas in the processing gas supplied into the plasma processing chamber 10 becomes 70% by volume or more of the total flow of the processing gas. To execute Step S13, the controller 2 controls the exhaust system 40 such that the pressure in the plasma processing chamber 10 becomes a specified pressure. To execute Step S13, the controller 2 controls the component/components of the power source 30, for example, the first RF generator 31a and/or the second RF generator 31b to supply first high frequency power and/or second high frequency power to generate plasma from the processing gas in the plasma processing chamber 10.

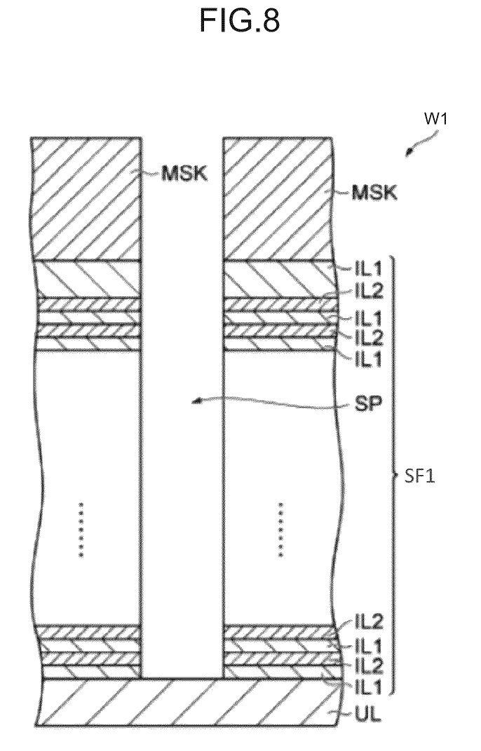

At Step S13, the second RF generator 31b may supply the second high frequency power of 5 W/cm² or more (that is, high frequency power for biasing) to the substrate support unit 11 to attract ions from the plasma into the substrate W. The second high frequency power of 5 W/cm² or more allows the ions from the plasma to sufficiently reach a bottom portion of the space (for example, a space SP illustrated in FIG. 8) formed in the film SF1 by the etching.

Instead of the high frequency power for biasing, a pulse voltage other than a high frequency voltage may be supplied to the substrate support unit 11. The pulse voltage is a pulsed voltage supplied from a pulse power source. The pulse power source may be configured to supply a pulse wave, or may have a device downstream from the pulse power source and for pulsing a voltage. In one example, the pulse voltage is supplied to the substrate support unit 11 such that negative potential is generated in the substrate W1. The pulse voltage may be a pulsed direct current voltage having a negative polarity. Furthermore, the pulse voltage may have pulses of a rectangular wave, pulses of a triangular wave, an impulse, or pulses of any other voltage waveform.

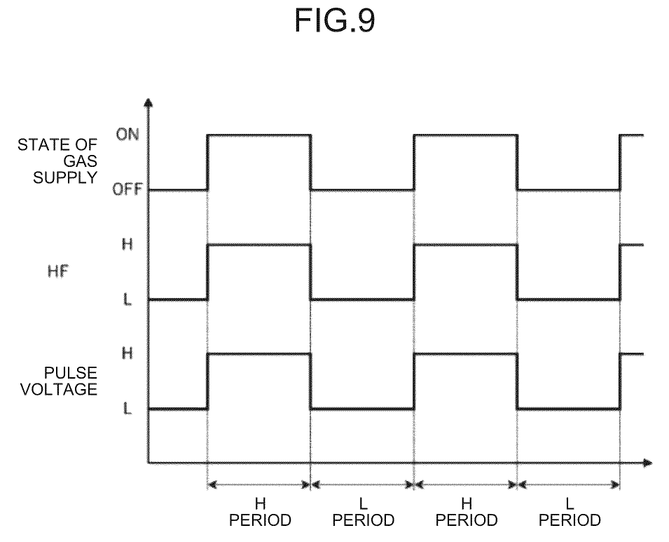

FIG. 9 is an example of a timing chart related to the substrate processing method according to the second embodiment. In FIG. 9, the horizontal axis represents time. In FIG. 9, the vertical axis represents states of supply of the first processing gas, levels of the first high frequency power HF, and levels of the pulse voltage. In FIG. 9, the first processing gas is periodically supplied into the plasma processing chamber 10. Furthermore, pulses of the first high frequency power and the pulse voltage are periodically supplied to the substrate support unit 11. The time periods, over which the pulses of the first high frequency power HF are supplied, the time period, over which the pulse voltage is supplied, and the time period, over which the first processing gas is supplied, are in synchronization with one another. The first processing gas may be continuously supplied into the plasma processing chamber 10.

In FIG. 9, the “L” level of the first high frequency power HF indicates that the first high frequency power HF is not being supplied or the power level of the first high frequency power HF is lower than the power level indicated by “H”. The “L” level of the pulse voltage indicates that the pulse voltage is not being provided to the substrate support unit 11 or the level of the pulse voltage is lower than the level indicated by “H”. Furthermore, the state, “ON”, of supply of the first processing gas indicates that the first processing gas is being supplied into the plasma processing chamber 10 and the state, “OFF”, of supply of the first processing gas indicates that supply of the first processing gas into the plasma processing chamber 10 has been stopped. The time period, over which the voltage level of the pulse voltage is L, will be referred to as an “L period” and the time period, over which the voltage level of the pulse voltage is H will be referred to as an “H period”.

The frequency (first frequency) of the pulse voltage in the H period may be controlled to be 100 kHz to 3.2 MHZ. In one example, the first frequency is controlled to be 400 kHz. In this case, a duty ratio (first duty ratio) indicating a ratio of a time period, over which the level of the pulse voltage is H, to one period may be 50% or less or 30% or less.

Furthermore, the frequency of the pulse voltage periodically supplied, that is, a frequency (second frequency) defining the period of the H period may be 1 kHz to 200 kHz, or 5 Hz to 100 kHz. In this case, a duty ratio (second duty ratio) indicating a ratio of the H period to one period may be 50% to 90%.

In the case described above with respect to the second embodiment, the time periods, over which the pulses of the first high frequency power HF are supplied, the time period, over which the pulse voltage is supplied, and the time period, over which the first processing gas is supplied, are in synchronization with one another, but these time periods may be not in synchronization with one another.

Adjusting the temperature of the electrostatic chuck 1111 at Step S13 to a low temperature, for example, −50° C. or lower promotes adsorption of the etchant to the substrate surface and thus enable the etching rate to be improved. In a case where the first processing gas includes a phosphorus-containing gas, the temperature of the electrostatic chuck 1111 may be adjusted in accordance with the ratio of the phosphorus-containing gas to the first processing gas.

When execution of Step S13 is ended, the substrate processing method according to the second embodiment is ended. FIG. 8 is an enlarged sectional view of part of an example of a substrate after execution of the substrate processing method illustrated in FIG. 6. Execution of the substrate processing method according to the second embodiment results in formation of the space SP reaching the underlayer UL, for example, in the film SF1, as illustrated in FIG. 8. As described above, the temperature adjusting system 50 enables control such that the electrostatic chuck 1111 and the substrate W1 are at the predetermined temperature in a process in a low temperature range.

### Third Embodiment

A substrate processing method using the temperature adjusting method according to the first embodiment will be described next as a third embodiment. A substrate processing apparatus in the third embodiment has a configuration similar to that of the first embodiment and description of any component and any operation that are the same will thus be omitted.

### Substrate Processing Method

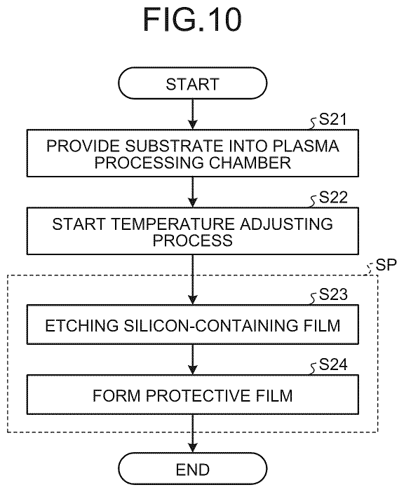

Another substrate processing method using the above described temperature adjusting method will be described by use of FIG. 10 to FIG. 13. FIG. 10 is a flowchart illustrating an example of substrate processing according to the third embodiment. The substrate processing method illustrated in FIG. 10 is applied to a substrate having a silicon-containing film. In the substrate processing method according to the third embodiment, the silicon-containing film is subjected to etching.

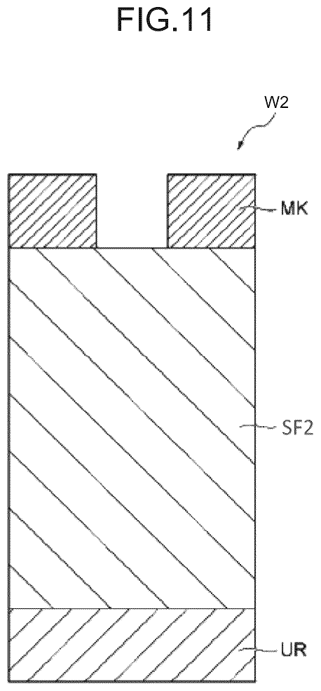

FIG. 11 is an enlarged sectional view of part of an example of a substrate provided according to the third embodiment. A substrate W2 illustrated in FIG. 11 may be used in manufacture of a device, such as a dynamic random access memory (DRAM) or a 3D-NAND. The substrate W2 has a silicon-containing film SF2. The substrate W2 may further have an underlying region UR. The silicon-containing film SF2 may be provided on the underlying region UR.

The silicon-containing film SF2 may be a silicon-containing dielectric film. The silicon-containing dielectric film may include a silicon oxide film or a silicon nitride film. The silicon-containing dielectric film may be a film of any other film species containing silicon. Furthermore, the silicon-containing film SF2 may include a silicon film (for example, a polycrystalline silicon film). Furthermore, the silicon-containing film SF2 may include at least one selected from a group including a silicon nitride film, a polycrystalline silicon film, a carbon-containing silicon film, and a low dielectric constant film. The carbon-containing silicon film may include a SiC film and/or a SiOC film. The low dielectric constant film may include silicon and may be used as an interlayer insulating film. Furthermore, the silicon-containing film SF2 may include two or more silicon-containing films of film species different from one another. The two or more silicon-containing films may include a silicon oxide film and a silicon nitride film. The silicon-containing film SF2 may be a multilayered film including one or more silicon oxide films and one or more silicon nitride films alternately layered over each other. The silicon-containing film SF2 may be a multilayered film including plural silicon oxide films and plural silicon nitride films alternately layered over each other. Or the two or more silicon-containing films may include a silicon oxide film and a silicon film. The silicon-containing film SF2 may be a multilayered film including one or more silicon oxide films and one or more silicon films alternately layered over each other. The silicon-containing film SF2 may be a multilayered film including plural silicon oxide films and plural polycrystalline silicon films alternately layered over each other. Or the two or more silicon-containing films may include a silicon oxide film, a silicon nitride film, and a silicon film.

The substrate W2 may further have a mask MK. The mask MK is provided on the silicon-containing film SF2. The mask MK is formed from a material having an etching rate lower than an etching rate of the silicon-containing film SF2 at Step S23 of the substrate processing method described later. The mask MK may be formed from an organic material. That is, the mask MK may contain carbon. The mask MK may be formed from, for example, an amorphous carbon film, a photoresist film, or a spin-on carbon film (SOC film). Or the mask MK may be formed from a silicon-containing film, such as a silicon-containing antireflection film. Or the mask MK may be a metal-containing mask formed from a metal-containing material, such as titanium nitride, tungsten, or tungsten carbide. The mask MK may have a thickness of 3 μm or more.

The mask MK has been patterned. That is, the mask MK has a pattern to be transferred to the silicon-containing film SF2 at Step S23 of the substrate processing method. As the pattern of the mask MK is transferred to the silicon-containing film SF2, an opening (recess), such as a hole or a trench, is formed in the silicon-containing film SF2. At Step S23, the aspect ratio of the opening formed in the silicon-containing film SF2 may be 20 or more, 30 or more, 40 or more, or 50 or more. The mask MK may have a line-and-space pattern.

The description of FIG. 10 will now be resumed. In a case described hereinafter as an example, the substrate processing method according to the third embodiment is applied to the substrate W2 illustrated in FIG. 11 by use of a plasma processing system. In the case where the plasma processing system is used, the substrate processing method may be executed at the plasma processing apparatus 1 through control of each component of the plasma processing apparatus 1 by the controller 2. The control of each component of the plasma processing apparatus 1 by the controller 2 for execution of the substrate processing method will also be described hereinafter.

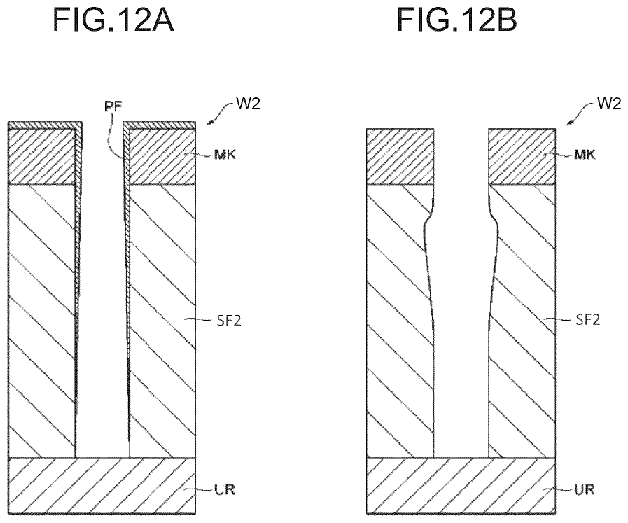

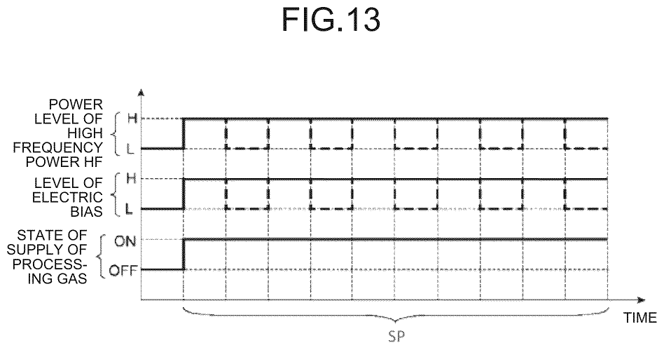

In the following description, reference will be made to FIG. 12A, FIG. 12B, and FIG. 13, in addition to FIG. 10. FIG. 12A is an enlarged sectional view of part of a substrate in an example, to which the substrate processing method illustrated in FIG. 10 has been applied, and FIG. 12B is an enlarged sectional view of part of a substrate in an example, the substrate having been subjected to etching by use of plasma formed from a processing gas not including phosphorus. FIG. 13 is an example of a timing chart related to the substrate processing method according to the third embodiment. In FIG. 13, the horizontal axis represents time. In FIG. 13, the vertical axis represents power levels of high frequency power HF, levels of electric biases, and states of supply of the processing gas. The “L” level of the high frequency power HF indicates that the high frequency power HF is not being supplied or the power level of the high frequency power HF is lower than the power level indicated by “H”. The “L” level of an electric bias indicates that the electric bias is not being provided to the lower electrode or the level of the electric bias is lower than the level indicated by “H”. Furthermore, the state, “ON”, of supply of the processing gas indicates that the processing gas is being supplied into the plasma processing chamber 10, and the state, “OFF”, of supply of the processing gas indicates that supply of the processing gas into the plasma processing chamber 10 has been stopped.

As illustrated in FIG. 10, the controller 2 controls the plasma processing apparatus 1 such that the substrate W2 is provided into the plasma processing chamber 10 (Step S21). The substrate W2 is placed on the electrostatic chuck 1111 and held by the electrostatic chuck 1111.

The controller 2 controls the temperature adjusting system 50 and starts the temperature adjusting process so that the temperature of the substrate support unit 11 (the electrostatic chuck 1111 and the substrate W1) becomes the predetermined temperature (Step S22). That is, the controller 2 instructs the controller 60 of the temperature adjusting system 50 to execute the temperature adjusting process according to the first embodiment. The temperature adjusting process is the same as that according to the first embodiment and description thereof will thus be omitted.

When the temperature of the substrate W2 becomes the predetermined temperature through the temperature adjusting process, the controller 2 controls the plasma processing apparatus 1 to execute Step SP. At Step SP, plasma processing for the substrate W2 is executed. At Step SP, plasma is generated from the processing gas in the plasma processing chamber 10. The substrate processing method according to the third embodiment includes Step S23. Step S23 is performed while Step SP is being executed. The substrate processing method according to the third embodiment may further include Step S24. Step S24 is performed while Step SP is being executed. Step S23 and Step S24 may be simultaneously executed or may be executed independently from each other.

At Step S23, the silicon-containing film SF2 is subjected to etching by use of a chemical species from the plasma generated from the processing gas in the plasma processing chamber 10 at Step SP. At Step S24, a protective film PF is formed on the substrate W2 by use of a chemical species from the plasma generated from the processing gas in the plasma processing chamber 10 at Step SP. The protective film PF is formed on a side wall surface defining the opening formed in the silicon-containing film SF2.

The processing gas used at Step SP includes a halogen element and phosphorus. The halogen element included in the processing gas may be fluorine. The processing gas may include at least one halogen-containing molecule. The processing gas may include, as the at least one halogen-containing molecule, at least one of a fluorocarbon or a hydrofluorocarbon. The fluorocarbon is, for example, at least one of CF4, C3F8, C4F6, or C4F8. The hydrofluorocarbon is, for example, at least one of CH2F2, CHF3, or CH3F. The hydrofluorocarbon may include two or more carbons. The hydrofluorocarbon may include, for example, three carbons or four carbons.

The processing gas may include at least one phosphorus-containing molecule. The phosphorus-containing molecule may be an oxide, such as tetraphosphorus decoxide (P4O10), tetraphosphorus octoxide (P4O8), or tetraphosphorus hexoxide (P4O6). Tetraphosphorus decoxide may also be called diphosphorus pentoxide (P2O5). The phosphorus-containing molecule may be a halide, such as phosphorus trifluoride (PF3), phosphorus pentafluoride (PF5), phosphorus trichloride (PCl3), phosphorus pentachloride (PCl5), phosphorus tribromide (PBr3), phosphorus pentabromide (PBr5), or phosphorus iodide (PI3). That is, the molecule including phosphorus may include fluorine as a halogen element. Or the molecule including phosphorus may include a halogen element other than fluorine, as the halogen element. The phosphorus-containing molecule may be a phosphoryl halide, such as phosphoryl fluoride (POF3), phosphoryl chloride (POCl3), or phosphoryl bromide (POBr3). The phosphorus-containing molecule may be phosphine (PH3), calcium phosphide (such as Ca3P2), phosphoric acid (H3PO4), sodium phosphate (Na3PO4), or hexafluorophosphoric acid (HPF6). The phosphorus-containing molecule may be a fluorophosphine (HxPFy). The sum of x and y is 3 or 5. Examples of the fluorophosphine include HPF2 and H2PF3. The processing gas may include, as the at least one phosphorus-containing molecule, one or more phosphorus-containing molecules of the phosphorus-containing molecules mentioned above. For example, the processing gas may include, as the at least one phosphorus-containing molecule, at least one of PF3, PCl3, PF5, PCl5, POCl3, PH3, PBr3, or PBr5. In a case where the phosphorus-containing molecule or molecules included in the processing gas is/are liquid or solid, the phosphorus-containing molecule or molecules may be vaporized through heating, for example, and then supplied into the plasma processing chamber 10.

The processing gas used at Step SP may further include carbon and hydrogen. The processing gas may include, as a molecule including hydrogen, at least one of H2, hydrogen fluoride (HF), a hydrocarbon (CxHy), a hydrofluorocarbon (CHxFy), or NH3. The hydrocarbon is, for example, CH4 or C3H6. Each of x and y is a natural number. The processing gas may include, as a molecule including carbon, a fluorocarbon or a hydrocarbon (for example, CH4). The processing gas may further include oxygen. The processing gas may include, for example, O2. Or the processing gas may include no oxygen.

In one embodiment, the processing gas includes a phosphorus-containing gas, a fluorine-containing gas, and a hydrogen-containing gas. The hydrogen-containing gas contains at least one selected from a group consisting of hydrogen fluoride, H2, ammonia (NH3), and a hydrocarbon. The phosphorus-containing gas includes at least one of the phosphorus-containing molecules mentioned above. The fluorine-containing gas includes at least one gas selected from a group consisting of: a fluorocarbon gas; and a fluorine-containing gas not containing carbon. The fluorocarbon gas is a gas containing the fluorocarbon mentioned above. The fluorine-containing gas not containing carbon is, for example, nitrogen trifluoride gas (NF3 gas) or sulfur hexafluoride gas (SF6 gas). Furthermore, the processing gas may further include a hydrofluorocarbon gas. The hydrofluorocarbon gas is gas of the hydrofluorocarbon mentioned above. Furthermore, the processing gas may further include a halogen-containing gas containing a halogen element other than fluorine. The halogen-containing gas is, for example, Cl2 gas and/or HBr gas.

An example of the processing gas includes a phosphorus-containing gas, a fluorocarbon gas, a hydrogen-containing gas, and an oxygen-containing gas (for example, 02 gas), or substantially consists of these gases. Another example of the processing gas includes a phosphorus-containing gas, a fluorine-containing gas not containing carbon, a fluorocarbon gas, a hydrogen-containing gas, a hydrofluorocarbon gas, and a halogen-containing gas containing a halogen element other than fluorine, or substantially consists of these gases.

In another embodiment, the processing gas includes the phosphorus-containing gas mentioned above, the fluorine-containing gas mentioned above, the hydrofluorocarbon gas mentioned above, and the above mentioned halogen-containing gas containing a halogen element other than fluorine, or substantially consists of these gases.

In one embodiment, the processing gas may include a first gas and a second gas. The first gas is gas not containing phosphorus. That is, the first gas is all of gases other than a phosphorus-containing gas included in the processing gas. The first gas may include a halogen element. The first gas may include gas of the above mentioned at least one halogen-containing molecule. The first gas may further include carbon and hydrogen. The first gas may further include gas of the above mentioned molecule including hydrogen and/or gas of the above described molecule including carbon. The first gas may further include oxygen. The first gas may include O2 gas. Or the first gas may include no oxygen. The second gas is a gas containing phosphorus. That is, the second gas is the phosphorus-containing gas mentioned above. The second gas may include gas of the above mentioned at least one phosphorus-containing molecule.

A flow ratio that is a ratio of the flow of the second gas to the flow of the first gas in the processing gas used at Step SP may be set to a value larger than 0 and equal to or less than 0.5. The flow ratio may be set to 0.075 or more and 0.3 or less. The flow ratio may be set to 0.1 or more and 0.25 or less.

As illustrated in FIG. 13, at Step SP, the processing gas is supplied into the plasma processing chamber 10. At Step SP, the pressure of the gas in the plasma processing chamber 10 is set to a specified pressure. At Step SP, the pressure of the gas in the plasma processing chamber 10 may be set to a pressure of 5 mTorr (0.65 Pa) or more and 100 mTorr (13.3 Pa) or less. Furthermore, at Step SP, high frequency power HF is supplied, to generate plasma from the processing gas in the plasma processing chamber 10. As represented by a solid line in FIG. 13, at Step SP, a continuous wave of high frequency power HF may be supplied. At Step SP, high frequency power LF may be used instead of the high frequency power HF. At Step SP, both high frequency power HF and an electric bias may be supplied. As represented by a sloid line in FIG. 13, a continuous wave of the electric bias may be provided to the lower electrode at Step SP. The power level of the high frequency power HF may be set to a level of 2 kW or more and 10 kW or less. In a case where high frequency power LF is used as the electric bias, the power level of the high frequency power LF may be set to a level of 2 kW or more. The power level of the high frequency power LF may be set to a level of 10 kW or more. To execute Step SP, the controller 2 controls the gas supply unit 20 to supply the processing gas into the plasma processing chamber 10. Furthermore, the controller 2 controls the exhaust system 40 to set the pressure of the gas in the plasma processing chamber 10 to a specified pressure. Furthermore, the controller 2 controls the components of the power source 30, for example, the first RF generator 31a and the second RF generator 31b, to supply the high frequency power HF, the high frequency power LF, or the high frequency power HF and the electric bias.

To execute Step S23, the controller 2 controls the gas supply unit 20 to supply the processing gas into the plasma processing chamber 10. Furthermore, the controller 2 controls the exhaust system 40 to set the pressure of the gas in the plasma processing chamber 10 to a specified pressure. Furthermore, the controller 2 controls the components of the power source 30, for example, the first RF generator 31a and the second RF generator 31b, to supply the high frequency power HF, the high frequency power LF, or the high frequency power HF and the electric bias.

In the substrate processing method according to the third embodiment, the temperature of the substrate W2 at the time of the start of Step S23 (or Step SP) may be set to a temperature of −50° C. or less. Setting the temperature of the substrate W2 to such a temperature increases the etching rate of the silicon-containing film SF2 at Step S23. The controller 2 may control the temperature adjusting system 50 as described above, to set the temperature of the substrate W2 at the time of the start of Step S23.

At Step S23, the silicon-containing film SF2 is subjected to etching by use of a halogen chemical species from the plasma generated from the processing gas. In the third embodiment, part of the whole area of the silicon-containing film SF2 is subjected to etching (see FIG. 12A), the part being exposed from the mask MK.

In a case where the processing gas includes, as the phosphorus-containing molecule, a molecule containing phosphorus and a halogen element, such as PF3, the halogen chemical species derived from that molecule contributes to the etching of the silicon-containing film SF2. Therefore, a phosphorus-containing molecule containing phosphorus and a halogen element, such as PF3, increases the etching rate of the silicon-containing film SF2 at Step S23.

At Step S24, the protective film PF is formed on the side wall surface defining the opening formed in the silicon-containing film SF2 by the etching at Step S23 (see in FIG. 12A). The protective film PF is formed of a chemical species from the plasma generated from the processing gas in the plasma processing chamber 10 at Step SP. Step S24 may be performed simultaneously with Step S23. As illustrated in FIG. 12A, in one embodiment, the protective film PF may be formed so as to decrease in thickness along a depth direction of the opening formed in the silicon-containing film SF2.

The protective film PF includes silicon and phosphorus that is included in the processing gas used at Step SP. In one embodiment, the protective film PF may further include carbon and/or hydrogen included in the processing gas. In one embodiment, the protective film PF may further include oxygen included in the processing gas or included in the silicon-containing film SF2. In one embodiment, the protective film PF may include phosphorus-oxygen bonds.

In one embodiment, the plasma of the processing gas described above includes plasma generated from hydrogen fluoride. In one embodiment, hydrogen fluoride may be the chemical species included most among the chemical species included in the plasma generated from the processing gas. In a state where a phosphorus chemical species generated from a phosphorus-containing gas (a gas including the phosphorus-containing molecule mentioned above) is present on a surface of the substrate W2, adsorption of hydrogen fluoride, that is, an etchant, to the substrate W2 is promoted. That is, in a state where the phosphorus chemical species generated from the phosphorus-containing gas is present on the surface of the substrate W2, supply of the etchant to the bottom of the opening (recess) is promoted and the etching rate of the silicon-containing film SF2 is increased.

Furthermore, if the processing gas does not include phosphorus, as illustrated in FIG. 12B, etching of the silicon-containing film SF2 would take place also in a horizontal direction. As a result, part of the opening formed in the silicon-containing film SF2 increases in width. For example, the width of the opening formed in the silicon-containing film SF2 partly increases near the mask MK.

By contrast, in the substrate processing method according to the third embodiment, the protective film PF is formed on the side wall surface defining the opening formed by etching in the silicon-containing film SF2. Etching of the silicon-containing film SF2 is thus performed with the side wall surface being protected by this protective film PF. Therefore, the substrate processing method according to the third embodiment enables minimization of etching in the horizontal direction in plasma etching of the silicon-containing film SF2.

In one embodiment, during a time period, in which Step SP is ongoing, that is, a time period, in which plasma is being generated from the processing gas at Step SP, one or more cycles each including Step S23 and Step S24 may be sequentially executed. At Step SP, two or more of the cycles may be executed sequentially.

In one embodiment, as represented by a broken line in FIG. 13, a pulse wave of the electric bias mentioned above may be provided to the lower electrode from the second RF generator 31b at Step SP. That is, when the plasma generated from the processing gas is present in the plasma processing chamber 10, the pulse wave of the electric bias may be provided to the lower electrode from the second RF generator 31b. In this embodiment, the etching of the silicon-containing film SF2 at Step S23 occurs mainly in the H periods within the period of the pulse wave of the electric bias. Furthermore, formation of the protective film PF at Step S24 occurs in the L periods within the period of the pulse wave of the electric bias.

In a case where the electric bias is high frequency power LF, the power level of the high frequency power LF in the H period within the period of the pulse wave of the electric bias may be set to a level of 2 kW or more. The power level of the high frequency power LF may be set to a level of 10 kW or more in the H period within the period of the pulse wave of the electric bias. As represented by a broken line in FIG. 13, in one embodiment, a pulse wave of the high frequency power HF described above may be supplied at Step SP. The power level of the high frequency power HF in the H period within the period of the pulse wave of the high frequency power HF may be set to a level of 1 kW or more and 10 kW or less. As illustrated in FIG. 13, the period of the pulse wave of the high frequency power HF may be in synchronization with the period of the pulse wave of the electric bias. As illustrated in FIG. 13, the H periods in the period of the pulse wave of the high frequency power HF may be in synchronization with the H periods in the period of the pulse wave of the electric bias. Or the H periods in the period of the pulse wave of the high frequency power HF may be not in synchronization with the H periods in the period of the pulse wave of the electric bias. The H periods in the period of the pulse wave of the high frequency power HF may each have a time length that is the same as or different from the time length of each of the H periods in the period of the pulse wave of the electric bias.

As described above, according to the embodiments, the temperature adjusting system 50 is a temperature adjusting system to cool the part (the electrostatic chuck 1111 and/or the substrate W) in the plasma processing chamber 10, and includes: the condenser 53 that condenses a temperature adjusting medium including at least one of C3F8 and C3H2F4; the heat exchanger 56 that cools the temperature adjusting medium condensed by the condenser 53; the temperature adjusting unit (base 1110) that cools the part to −150° C. or more and −50° C. or less by heat exchange with the temperature adjusting medium cooled by the heat exchanger 56; and the pump 55 that circulates the temperature adjusting medium. As a result, the temperature adjusting system 50 is able to be used in a low temperature range.

Furthermore, according to the embodiments, the viscosity of the temperature adjusting medium is 6 mPa·sec or less. As a result, the load on the pump 55 is able to be reduced also in a low temperature range.

Furthermore, according to the embodiments, the temperature adjusting system 50 is a temperature adjusting system to cool the part (the electrostatic chuck 1111 and/or the substrate W) in the plasma processing chamber 10, and includes: the condenser 53 that condenses a temperature adjusting medium that is in a gaseous state at normal temperature and normal pressure; the heat exchanger 56 that cools the temperature adjusting medium condensed by the condenser 53; the temperature adjusting unit (base 1110) that cools the part by heat exchange with the temperature adjusting medium cooled by the heat exchanger 56; and the pump 55 that circulates the temperature adjusting medium. As a result, the temperature adjusting system 50 is able to be used in a low temperature range.

Furthermore, according to the embodiments, the temperature adjusting system 50 is a temperature adjusting system to cool the part (the electrostatic chuck 1111 and/or the substrate W) in the plasma processing chamber 10 by use of a temperature adjusting medium that is in a gaseous state at normal temperature and normal pressure, and includes: the heat exchanger 56 that cools the temperature adjusting medium that has condensed; the temperature adjusting unit (base 1110) that cools the part by heat exchange with the temperature adjusting medium cooled by the heat exchanger 56; and the pump 55 that circulates the temperature adjusting medium. As a result, the temperature adjusting system 50 is able to be used in a low temperature range.

Furthermore, according to the embodiments, the temperature adjusting medium subjected to heat exchange by the temperature adjusting unit is condensed into liquid again by the condenser 53 to condense the temperature adjusting medium. As a result, the temperature adjusting medium that has turned into the gaseous phase after heat exchange is able to be returned to the liquid phase and circulated.

Furthermore, according to the embodiments, the temperature adjusting medium is cooled by the heat exchanger 56 to the predetermined temperature. As a result, the temperature adjusting medium at the predetermined temperature is able to be circulated through the temperature adjusting unit.

Furthermore, according to the embodiments, the viscosity of the temperature adjusting medium at the predetermined temperature is 6 mPa·sec or less. As a result, the load on the pump 55 is able to be reduced also in a low temperature range.

Furthermore, according to the embodiments, the temperature adjusting medium is in the liquid phase in the equilibrium state at the predetermined temperature and at atmospheric pressure or more. As a result, the temperature adjusting medium is able to be readily circulated by the pump 55 in a low temperature range. Furthermore, because the vapor pressure of the temperature adjusting medium is sufficiently low, degradation of the cooling performance due to any dryout is able to be minimized.

Furthermore, according to the embodiments, the temperature adjusting medium is allowed to include the gaseous phase in the flow channel inside the temperature adjusting unit. As a result, even if heat is input to the part from the plasma due to the high RF power, the temperature of the part is able to be controlled to be at the target temperature.

Furthermore, according to the embodiments, the temperature adjusting medium is C3F8 or C3H2F4. As a result, the temperature adjusting system 50 is able to be used in a low temperature range.

Furthermore, according to the embodiments, the predetermined temperature is a temperature in the range of −150° C. or more and −50° C. or less. As a result, increase in the viscosity of the temperature adjusting medium in a low temperature range is able to be minimized. Furthermore, because the vapor pressure of the temperature adjusting medium is sufficiently low, degradation of the cooling performance due to any dryout is able to be minimized.

Furthermore, according to the embodiments, the heat exchanger 56 cools the temperature adjusting medium by heat exchange with a coolant. As a result, the temperature adjusting medium is able to be cooled to the predetermined temperature.

Furthermore, according to the embodiments, the coolant is liquid nitrogen. As a result, the temperature adjusting medium is able to be cooled to the predetermined temperature.

Furthermore, according to the embodiments, the part include a substrate placing pedestal (substrate support unit 11). As a result, the substrate W is able to be cooled to the predetermined temperature.

Furthermore, according to the embodiments, the heat input to the part is 1 kW or more. As a result, even if heat is input to the part from the plasma due to the high RF power, the temperature of the part is able to be controlled to be at the target temperature.

Furthermore, according to the embodiments, the temperature adjusting method is a temperature adjusting method to cool a part (the electrostatic chuck 1111 and/or the substrate W) in the plasma processing chamber 10, and includes: (a) a process of condensing, by means of the condenser 53, a temperature adjusting medium that is in the gaseous state at normal temperature and normal pressure; (b) a process of cooling, by means of the heat exchanger 56, the temperature adjusting medium that has been condensed by the condenser 53; (c) a process of supplying the temperature adjusting medium that has been cooled by the heat exchanger 56 to the temperature adjusting unit (the base 1110) that cools the part; (d) a process of cooling, at the temperature adjusting unit, the part by heat exchange with the temperature adjusting medium; (e) a process of returning the temperature adjusting medium that has been subjected to the heat exchange at the temperature adjusting unit, to the condenser 53; and (f) a process of repeating (a) to (e). As a result, use in a low temperature range is enabled. Furthermore, because the vapor pressure of the temperature adjusting medium is sufficiently low, degradation of the cooling performance due to any dryout is able to be minimized.

The embodiments disclosed herein are just examples in all aspects, and should not be construed as being limiting in any way. Various omissions, substitutions, and modifications may be made to the above described embodiments, without departing from the scope and gist of the appended claims.

Furthermore, with respect to each of the above described embodiments, the electrostatic chuck 1111 and the substrate W, W1, or W2 have been described as an example of the part to be cooled, but the embodiments are not limited to such examples. For example, the part to be cooled may be any part required to be cooled, such as the shower head 13, the upper electrode, the side wall 10a of the plasma processing chamber 10, or the ring assembly 112.

Furthermore, with respect to each of the above described embodiments, the plasma processing apparatus 1 that subjects the substrate W, W1, or W2 to processing, such as etching, by use of capacitively coupled plasma serving as a plasma source has been described as an example, but the disclosed techniques are not limited to such an example. The plasma source is not necessarily capacitively coupled plasma, and any apparatus that subjects the substrate W, W1, or W2 to processing by use of plasma from any plasma source, such as inductively coupled plasma, microwave plasma, or magnetron plasma, for example, may be used.

The following notes are further disclosed in relation to the above described embodiments.

(1) A substrate processing method, including:
a process of providing a substrate into a plasma processing chamber, the substrate having: a silicon-containing film including a silicon oxide film; and a mask on the silicon-containing film;
a process of controlling temperature of a substrate support unit where the substrate is placed; and
a process of subjecting the silicon-containing film to etching by use of plasma generated from a first processing gas including: hydrogen fluoride gas; and at least one kind of carbon-containing gas selected from a group consisting of a fluorocarbon gas and a hydrofluorocarbon gas, flow of the hydrogen fluoride gas being the most in the first processing gas excluding inert gas, wherein
the process of controlling the temperature of the substrate support unit includes:
   (a) a process of condensing, by means of a condenser, a temperature adjusting medium including at least one selected from a group consisting of C3F8 and C3H2F4;
   (b) a process of cooling, by means of a heat exchanger, the temperature adjusting medium that has been condensed by the condenser;
   (c) a process of supplying the temperature adjusting medium that has been cooled to −150° C. or more and −50° C. or less by the heat exchanger, to a temperature adjusting unit that cools the substrate support unit;
   (d) a process of cooling, at the temperature adjusting unit, the substrate support unit by heat exchange with the temperature adjusting medium;
   (e) a process of returning the temperature adjusting medium that has been subjected to the heat exchange at the temperature adjusting unit, to the condenser; and
   (f) a process of repeating (a) to (e) above.
      (2) A substrate processing apparatus, comprising:
a plasma processing chamber comprising a substrate support unit where a substrate is placed inside;
a temperature adjusting system that adjusts temperature of the substrate support unit; and
a controller, wherein
the controller is configured to control the substrate processing apparatus to provide the substrate into the plasma processing apparatus, the substrate having: a silicon-containing film including a silicon oxide film; and a mask on the silicon-containing film,
the controller is configured to control the temperature adjusting system to control the temperature of the substrate support unit where the substrate is placed,
the controller is configured to control the substrate processing apparatus to subject the silicon-containing film to etching by use of plasma generated from a first processing gas including: hydrogen fluoride gas; and at least one kind of carbon-containing gas selected from a group consisting of a fluorocarbon gas and a hydrofluorocarbon gas, flow of the hydrogen fluoride gas being the most in the first processing gas excluding inert gas, and
for control of the temperature adjusting system by the controller,
   the controller is (a) configured to control the temperature adjusting system to condense, by means of a condenser, a temperature adjusting medium including at least one selected from a group consisting of C3F8 and C3H2F4,
   the controller is (b) configured to control the temperature adjusting system to cool, by means of a heat exchanger, the temperature adjusting medium that has been condensed by the condenser,
   the controller is (c) configured to control the temperature adjusting system to supply the temperature adjusting medium that has been cooled to −150° C. or more and −50° C. or less by the heat exchanger, to a temperature adjusting unit that cools the substrate support unit,
   the controller is (d) configured to control the temperature adjusting system to cool the substrate support unit by heat exchange with the temperature adjusting medium at the heat adjusting unit,
   the controller is (e) configured to control the temperature adjusting system to return the temperature adjusting medium that has been subjected to the heat exchange at the temperature adjusting unit, to the condenser, and
   the controller is (f) configured to control the temperature adjusting system to repeat (a) to (e) above.
      (3) A substrate processing method, including:
a process of providing a substrate into a plasma processing chamber, the substrate having: a silicon-containing film including a silicon oxide film; and a mask on the silicon-containing film;
a process of controlling temperature of a substrate support unit where the substrate is placed; and
a processing of subjecting the silicon-containing film to etching by use of plasma generated from a processing gas containing a phosphorus-containing gas and hydrogen fluoride, wherein
the process of controlling the temperature of the substrate support unit includes:
   (a) a process of condensing, by means of a condenser, a temperature adjusting medium that is in a gaseous state at normal temperature and normal pressure;
   (b) a process of cooling, by means of a heat exchanger, the temperature adjusting medium that has been condensed by the condenser;
   (c) a process of supplying the temperature adjusting medium that has been cooled to −150° C. or more and −50° C. or less by the heat exchanger, to a temperature adjusting unit that cools the substrate support unit;
   (d) a process of cooling, at the temperature adjusting unit, the substrate support unit by heat exchange with the temperature adjusting medium;
   (e) a process of returning the temperature adjusting medium that has been subjected to the heat exchange at the temperature adjusting unit, to the condenser; and
   (f) a process of repeating (a) to (e) above.
      (4) A substrate processing apparatus, comprising:
a plasma processing chamber comprising a substrate support unit where a substrate is placed inside;
a temperature adjusting system that adjusts temperature of the substrate support unit; and
a controller, wherein
the controller is configured to control the substrate processing apparatus to provide the substrate into the plasma processing chamber, the substrate having: a silicon-containing film including a silicon oxide film; and a mask on the silicon-containing film,
the controller is configured to control the temperature adjusting system to control the temperature of the substrate support unit where the substrate is placed,
the controller is configured to control the substrate processing apparatus to subject the silicon-containing film to etching by use of plasma generated from a processing gas containing a phosphorus-containing gas and hydrogen fluoride, and
for control of the temperature adjusting system by the controller,
   the controller is (a) configured to control the temperature adjusting system to condense, by means of a condenser, a temperature adjusting medium that is in a gaseous state at normal temperature and normal pressure,
   the controller is (b) configured to control the temperature adjusting system to cool, by means of a heat exchanger, the temperature adjusting medium that has been condensed by the condenser,
   the controller is (c) configured to control the temperature adjusting system to supply the temperature adjusting medium that has been cooled to −150° C. or more and −50° C. or less by the heat exchanger, to a temperature adjusting unit that cools the substrate support unit,
   the controller is (d) configured to control the temperature adjusting system to cool the substrate support unit by heat exchange with the temperature adjusting medium at the heat adjusting unit,
   the controller is (e) configured to control the temperature adjusting system to return the temperature adjusting medium that has been subjected to the heat exchange at the temperature adjusting unit, to the condenser, and
   the controller is (f) configured to control the temperature adjusting system to repeat (a) to (e) above.

The present disclosure enables use in a low temperature range.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A temperature adjusting system that cools a part in a plasma processing chamber, the temperature adjusting system comprising:
a condenser that condenses a temperature adjusting medium including at least one of C3F8 and C3H2F4;
a heat exchanger that cools the temperature adjusting medium that has been condensed by the condenser;
a temperature adjusting unit that cools the part to −150° C. or more and −50° C. or less by heat exchange with the temperature adjusting medium that has been cooled by the heat exchanger; and
a pump that circulates the temperature adjusting medium.

2. The temperature adjusting system according to claim 1, wherein the temperature adjusting medium has a viscosity of 6 mPa·sec or less.

3. The temperature adjusting system according to claim 1, wherein the temperature adjusting medium that has been subjected to the heat exchange at the temperature adjusting unit is condensed into liquid again at the condenser to condense the temperature adjusting medium.

4. The temperature adjusting system according to claim 1, wherein the temperature adjusting medium is cooled to a predetermined temperature at the heat exchanger.

5. The temperature adjusting system according to claim 4, wherein the temperature adjusting medium has a viscosity of 6 mPa·sec at the predetermined temperature.

6. The temperature adjusting system according to claim 4, wherein the temperature adjusting medium is in a liquid phase in an equilibrium state at the predetermined temperature and at atmospheric pressure or more.

7. The temperature adjusting system according to claim 6, wherein the temperature adjusting medium is allowed to include a gaseous phase in a flow channel inside the temperature adjusting unit.

8. The temperature adjusting system according to claim 7, wherein the temperature adjusting medium is C3F8 or C3H2F4.

9. The temperature adjusting system according to claim 4, wherein the predetermined temperature is a temperature in a range of −150° C. or more and −50° C. or less.

10. The temperature adjusting system according to claim 1, wherein the heat exchanger cools the temperature adjusting medium by heat exchange with a coolant.

11. The temperature adjusting system according to claim 10, wherein the coolant is liquid nitrogen.

12. The temperature adjusting system according to claim 1, wherein the part is a substrate placing pedestal.

13. The temperature adjusting system according to claim 1, wherein heat input to the part is 1 kW or more.

14. A substrate processing method, including:
a process of providing a substrate into a plasma processing chamber, the substrate having: a silicon-containing film including a silicon oxide film; and a mask on the silicon-containing film;
a process of controlling temperature of a substrate support unit where the substrate is placed; and
a process of subjecting the silicon-containing film to etching by use of plasma generated from a first processing gas including: hydrogen fluoride gas; and at least one kind of carbon-containing gas selected from a group consisting of a fluorocarbon gas and a hydrofluorocarbon gas, flow of the hydrogen fluoride gas being the most in the first processing gas excluding inert gas, wherein
the process of controlling the temperature of the substrate support unit includes:
(a) a process of condensing, by means of a condenser, a temperature adjusting medium including at least one selected from a group consisting of C3F8 and C3H2F4;
(b) a process of cooling, by means of a heat exchanger, the temperature adjusting medium that has been condensed by the condenser;
(c) a process of supplying the temperature adjusting medium that has been cooled to −150° C. or more and −50° C. or less by the heat exchanger, to a temperature adjusting unit that cools the substrate support unit;
(d) a process of cooling, at the temperature adjusting unit, the substrate support unit by heat exchange with the temperature adjusting medium;
(e) a process of returning the temperature adjusting medium that has been subjected to the heat exchange at the temperature adjusting unit, to the condenser; and
(f) a process of repeating (a) to (e) above.

15. A substrate processing apparatus, comprising:
a plasma processing chamber comprising a substrate support unit where a substrate is placed inside;
a temperature adjusting system that adjusts temperature of the substrate support unit; and
a controller, wherein
the controller is configured to control the substrate processing apparatus to provide the substrate into the plasma processing apparatus, the substrate having: a silicon-containing film including a silicon oxide film; and a mask on the silicon-containing film,
the controller is configured to control the temperature adjusting system to control the temperature of the substrate support unit where the substrate is placed,
the controller is configured to control the substrate processing apparatus to subject the silicon-containing film to etching by use of plasma generated from a first processing gas including: hydrogen fluoride gas; and at least one kind of carbon-containing gas selected from a group consisting of a fluorocarbon gas and a hydrofluorocarbon gas, flow of the hydrogen fluoride gas being the most in the first processing gas excluding inert gas, and
for control of the temperature adjusting system by the controller,
the controller is (a) configured to control the temperature adjusting system to condense, by means of a condenser, a temperature adjusting medium including at least one selected from a group consisting of C3F8 and C3H2F4,
the controller is (b) configured to control the temperature adjusting system to cool, by means of a heat exchanger, the temperature adjusting medium that has been condensed by the condenser,
the controller is (c) configured to control the temperature adjusting system to supply the temperature adjusting medium that has been cooled to −150° C. or more and −50° C. or less by the heat exchanger, to a temperature adjusting unit that cools the substrate support unit,
the controller is (d) configured to control the temperature adjusting system to cool the substrate support unit by heat exchange with the temperature adjusting medium at the heat adjusting unit,
the controller is (e) configured to control the temperature adjusting system to return the temperature adjusting medium that has been subjected to the heat exchange at the temperature adjusting unit, to the condenser, and
the controller is (f) configured to control the temperature adjusting system to repeat (a) to (e) above.
